(19) United States
(12) Patent Application Publication
(10) Pub. No.: US 2023/0295791 A1
(43) Pub. Date: Sep. 21, 2023

(54) MASK ASSEMBLIES AND EVAPORATION DEVICES

(71) Applicants: Chengdu BOE Optoelectronics Technology Co., Ltd., Chengdu, Sichuan (CN); BOE Technology Group Co., Ltd., Beijing (CN)

(72) Inventors: Jiangtao DENG, Beijing (CN); Peng XU, Beijing (CN)

(21) Appl. No.: 17/914,951

(22) PCT Filed: Oct. 28, 2021
(86) PCT No.: PCT/CN2021/126943

§ 371 Date: Sep. 27, 2022

(30) Foreign Application Priority Data
Mar. 11, 2021 (CN) 202110265765.8

(51) Int. Cl. C23C 14/04; C23C 14/24

(52) U.S. Cl. CPC C23C 14/042; C23C 14/24

(57) ABSTRACT

The present application provides a mask assembly and an evaporation device to effectively reduce a possibility that wrinkles are generated in a first mask and effectively avoid edge color mixing. The mask assembly includes a frame, and a first mask and a second mask stacked on the frame. The first mask includes a plurality of mask strips disposed along a first direction, and a gap is disposed between two adjacent mask strips. The second mask includes a body and support strips. The support strips include a plurality of first support strips disposed along the first direction and a plurality of second support strips disposed along a second direction. Widths of first ends of outermost first support strips and first ends of outermost second support strips gradually increase along a direction from being away from the body to being close to the body, and the first support strips are disposed corresponding to the gaps. The evaporation device includes the mask assembly.

### CROSS-REFERENCE TO RELATED APPLICATION

The present disclosure is a US national phase of PCT application No. PCT/CN2021/126943 filed on Oct. 28, 2021, which claims the priority of the Chinese Patent Application No. CN202110265765.8, filed on Mar. 11, 2021, the entire contents of which are incorporated herein by reference.

### TECHNICAL FIELD

The present application relates to the field of manufacturing technologies of display products and in particular to a mask assembly and an evaporation device.

### BACKGROUND

In the prior arts, an Organic Light-Emitting Diode (OLED) display is a display with autonomous light emission function. Due to its advantages such as small thickness, light weight, active illumination, fast response, wide view angle, rich color, high brightness, low power consumption and high, low temperature resistance, etc., the OLED display is widely applied in the display industry. In a manufacturing process of the OLED display, OLED materials are evaporated on a substrate through evaporation by using an evaporator in cooperation with a mask assembly, so as to form an organic light-emitting pattern on the substrate, thereby obtaining an array substrate.

A current mask assembly generally includes a metal frame 10′, a fine metal mask 20′ (FMM) and a full mask sheet 30′. The full mask sheet serves as a display screen blocking tool and performs blocking during evaporation such that a screen with a desired shape can be obtained through evaporation. The fine metal mask is used to evaporate a light-emitting layer material to form a pixel pattern on a backplate. The fine metal mask includes a plurality of fine metal mask strips 21′.

FIG. 1 is a structural schematic diagram illustrating a full mask sheet commonly used in manufacturing process of mobile phone products. FIG. 2 is a schematic diagram illustrating a correspondence between a fine metal mask and a full mask sheet in manufacturing process of mobile phone products. FIG. 3 is a structural schematic diagram illustrating a full mask sheet commonly used in wearable products. FIG. 4 is a schematic diagram illustrating a correspondence between a fine metal mask and a full mask sheet in wearable products.

As shown in FIGS. 1 to 4, the mobile phone products have a large width (no less than 5.1 inches), and one fine metal mask strip 21′ usually corresponds to one column of openings 311′ arranged on the full mask sheet 30′ whereas the wearable products such as wrist watch, wristband or the like have a smaller diameter or width (1.2 inches or 1.39 inches), and one fine metal mask strip 21′ usually corresponds to at least two columns of openings 311′ arranged on the full mask sheet 30′. Positions of support strips of the full mask sheet need to be set based on widths of the fine metal mask strips, so as to avoid affecting welding process of the fine metal mask and thus the risk of color mixing. Further, the wearable products mostly have circular openings, and based on current design idea of the full mask sheet, localized wrinkles may appear at four corners of the full mask sheet after tensioning is completed for the full mask sheet, which can be reflected in both actual tensioning result and simulation tensioning result. Levelness test results of openings M′, N′ 0′ and P′ at the four corners of the full mask sheet 30′ shown in FIG. 3 are indicated in FIG. 5: the four openings all have localized wrinkles which are approximate to 140 μm with maximum values appearing in circle m′ of the opening M′, the circle n′ of the opening N′, the circle o′ of the opening O′ and the circle p′ of the opening P′ marked in FIG. 3 (all are positions closest to corners of the mask). FIG. 6 shows a simulation tensioning result of the full mask sheet, from which it can also be seen that localized wrinkles are generated at the positions close to the corners of the template.

When large winkles are generated on the full mask sheet, the fine metal mask may be damaged by squeeze, resulting in edge color mixing.

### SUMMARY

The present application provides a mask assembly and an evaporation device. By designing the specific structure of the mask assembly, a possibility that wrinkles are generated in a first mask can be effectively reduced, thus effectively avoiding color mixing at edges.

According to a first aspect of embodiments of the present application, there is provided a mask assembly, including a frame, and a first mask and a second mask stacked on the frame, where the first mask is located at a side of the second mask away from the frame;

the first mask includes a plurality of mask strips disposed along a first direction, a gap is disposed between two adjacent mask strips, and a plurality of pixel openings are arranged in an array in each of the mask strips;

the second mask includes a body and support strips disposed along a periphery of the body, first ends of the support strips are connected with the body and second ends disposed opposite to the first ends are connected with the frame, a plurality of openings configured to define a shape of a display region are arranged in an array in the body, a size of the openings is less than a size of the mask strips, the support strips include a plurality of first support strips extending along the first direction and a plurality of second support strips extending along a second direction perpendicular to the first direction, the plurality of first support strips are spaced apart along the second direction, and the plurality of second support strips are spaced apart along the first direction;

widths of first ends of outermost first support strips and first ends of outermost second support strips gradually increase along a direction from away from the body to close to the body, and the first support strips are disposed corresponding to the gaps.

Optionally, rounded corners are disposed respectively at portions of two opposed edges of the first ends of the outermost first support strips and the first ends of the outermost second support strips joining the body.

Optionally, two opposed edges of the first ends of the outermost first support strips and the first ends of the outermost second support strips extend outwardly and obliquely along the direction from away from the body to close to the body;

the two opposed edges of the first ends of the outermost first support strips and the first ends of the outermost second support strips are in a shape of straight line or arc.

Optionally, widths of first ends of at least part of other first support strips gradually increase along the direction from away from the body to close to the body; and/or,

widths of first ends of at least part of other second support strips gradually increase along the direction from away from the body to close to the body.

Optionally, rounded corners are disposed respectively at portions of two opposed edges of the first ends of at least part of other first support strips joining the body; and/or,

rounded corners are disposed respectively at portions of two opposed edges of the first ends of at least part of other second support strips joining the body.

Optionally, a width of the second ends of the first support strips is less than or equal to a width of the gaps.

Optionally, a width of the second ends of the first support strips is a minimum width of the first support strips, which is 1.8 mm to 2.0 mm.

Optionally, edges of the body at which the first support strips are disposed are first edges and edges of the body at which the second support strips are disposed are second edges.

A distance D from an inner edge of the frame to a nearest first edge of the body is greater than 5 mm and less than a size of the openings in the first direction, and a length of the first support strips is no less than 5 mm longer than the distance D.

A distance K from the inner edge of the frame to a nearest second edge of the body is greater than 5 mm and less than a size of the openings in the second direction, and a length of the second support strips is no less than 5 mm longer than the distance K.

Optionally, a distance between two adjacent second support strips is greater than the size of the openings in the first direction.

According to a second aspect of embodiments of the present application, there is provided an evaporation device including the above mask assembly.

In the mask assembly and the evaporation device of the present application, the widths of the first ends of the outermost first support strips and the first ends of the outermost second support strips are disposed as gradually increasing along the direction from away from the body to close to the body, that is, the widths of the first support strips and the second support strips located at the corners of the body of the second mask are gradually widened along the direction from away from the body to close to the body, so as to increase the support for the body. In this way, a pull force for the body during a tensioning process can be better balanced, and a possibility that wrinkles are generated in the first mask can be effectively reduced, thus effectively avoiding edge color mixing.

### BRIEF DESCRIPTION OF THE DRAWINGS

FIG. 1 is a structural schematic diagram illustrating a full mask sheet commonly used in manufacturing process of mobile phone products.

FIG. 2 is a schematic diagram illustrating a correspondence between a fine metal mask and a full mask sheet in manufacturing process of mobile phone products.

FIG. 3 is a structural schematic diagram illustrating a full mask sheet commonly used in manufacturing process of wearable products.

FIG. 4 is a schematic diagram illustrating a correspondence between a fine metal mask and a full mask sheet in manufacturing process of wearable products.

FIG. 5 shows levelness test results of an opening M′, an opening N′, an opening O′ and an opening P′ of the full mask sheet in FIG. 1.

FIG. 6 shows a simulation tensioning result of a full mask sheet commonly used in wearable products.

FIG. 7 is a structural schematic diagram illustrating a mask assembly according to embodiment 1 of the present application.

FIG. 8 is a structural schematic diagram illustrating a first mask of a mask assembly according to embodiment 1 of the present application.

FIG. 9 is a structural schematic diagram illustrating a second mask of a mask assembly according to embodiment 1 of the present application.

FIG. 10 is a partially-enlarged view of part A in FIG. 9.

FIG. 11 is a structural schematic diagram illustrating a second mask and a frame of a mask assembly according to embodiment 1 of the present application.

FIG. 12 is a partially-enlarged view of part B in FIG. 11.

FIG. 13 shows levelness test results of an opening M, an opening N, an opening O and an opening P of the full mask sheet in FIG. 11.

FIG. 14 is a structural schematic diagram illustrating a second mask and a frame of a mask assembly according to embodiment 2 of the present application.

FIG. 15 is a partially-enlarged view of part C in FIG. 14.

FIG. 16 is a structural schematic diagram illustrating a first mask and a frame of another implementation of a mask assembly according to embodiment 2 of the present application.

FIG. 17 is a partially-enlarged view of part E in FIG. 16.

FIG. 18 is a structural schematic diagram illustrating a first mask and a frame of yet another implementation of a mask assembly according to embodiment 2 of the present application.

FIG. 19 is a partially-enlarged view of part F in FIG. 18.

FIG. 20 is a structural schematic diagram illustrating a second mask and a frame of a mask assembly according to embodiment 3 of the present application.

FIG. 21 is a partially-enlarged view of part Gin FIG. 20.

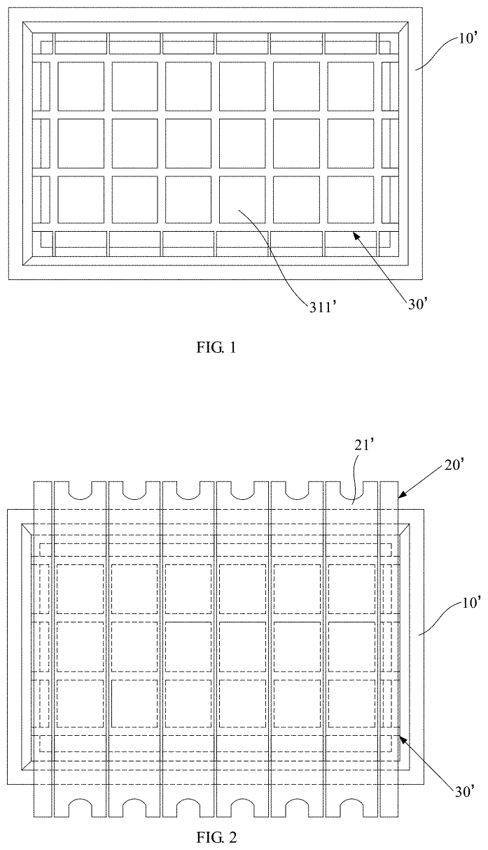

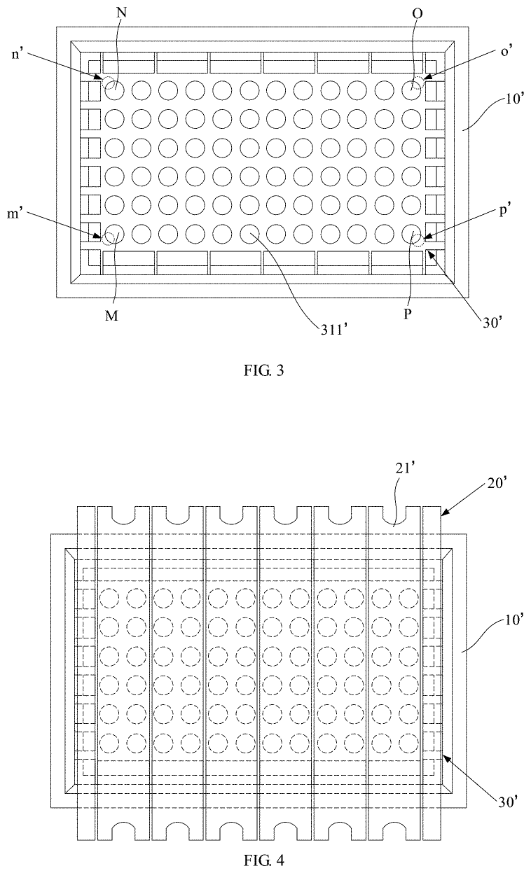

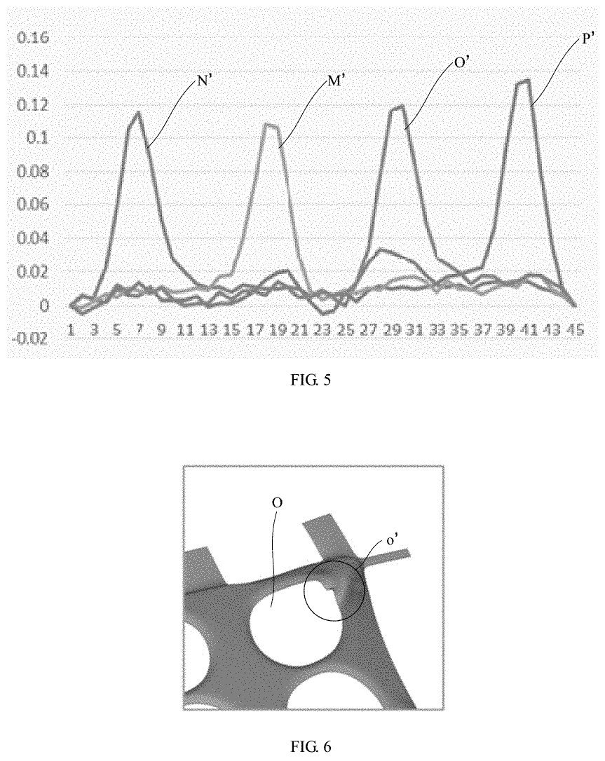

### DETAILED DESCRIPTION OF THE EMBODIMENTS

Illustrative embodiments will be described in detail herein, with the illustrations thereof represented in the drawings. When the following descriptions involve the drawings, like numerals in different drawings refer to like or similar elements unless otherwise indicated. The illustrative embodiments described in the following examples do not represent all embodiments consistent with the present application. Rather, they are merely embodiments of apparatuses and methods consistent with some aspects of the present application as detailed in the appended claims.

The terms used herein are used for the purpose of describing a particular embodiment only rather than limiting the present application. Unless otherwise stated, the technical terms or scientific terms used in the present application should have meanings that can be understood by persons of ordinary skills in the art. The terms “one” or “a” and the like used in the specification and the claims do not represent quantity limitation but represent at least one. The term “include” or “contain” or the like is intended to refer to that an element or object appearing before “include” or “contain” covers an element or object or its equivalents listed after “include” or “contain” and does not preclude other elements or objects. “Connect” or “connect with” or the like is not limited to physical or mechanical connection but includes direct or indirect electrical connection. “Plurality” includes two, which is equivalent to at least two. The singular forms such as “a”, ‘said”, and “the” used in the present application and the appended claims are also intended to include plural forms, unless the context clearly indicates otherwise. It is also to be understood that the term “and/or” as used herein refers to and includes any or all possible combinations of one or more associated listed items.

### Embodiment 1

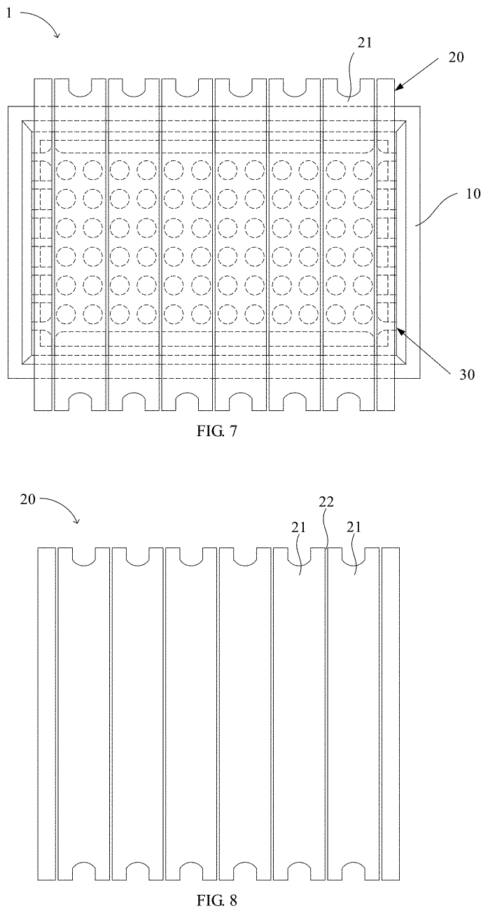

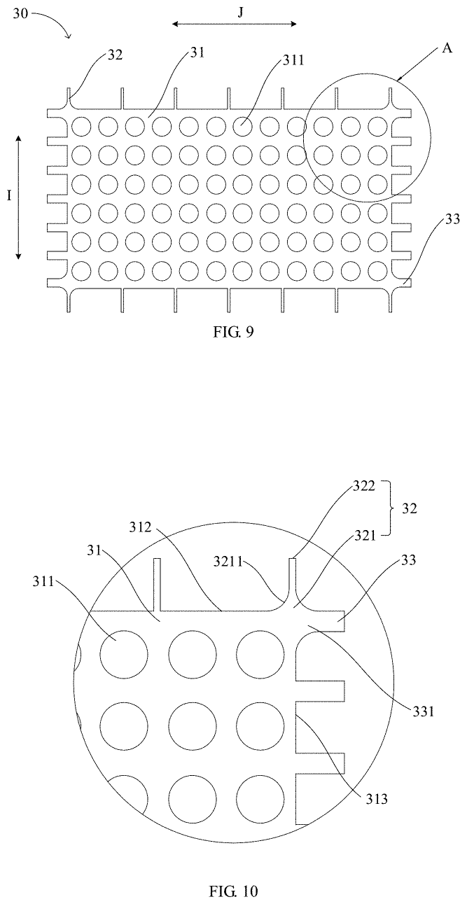

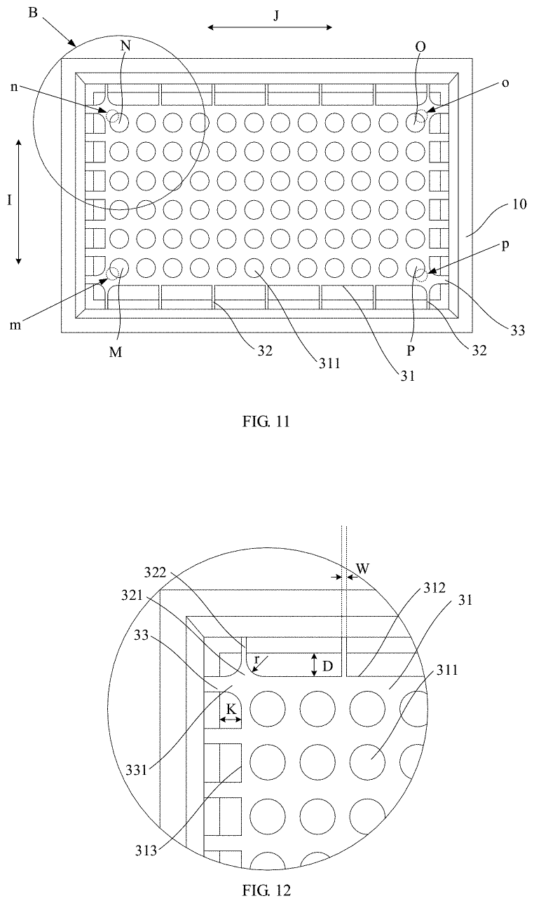

As understood in combination with FIGS. 7 to 13, this embodiment provides a mask assembly 1, including a frame 10, and a first mask 20 and a second mask 30 stacked on the frame 10. The first mask 20 is located at a side of the second mask 30 away from the frame 10.

The first mask 20 includes a plurality of mask strips 21 disposed along a first direction. A gap 22 is disposed between two adjacent mask strips 21, and a plurality of pixel openings 311 are arranged in an array in each of the mask strips 21. That is, the first mask 20 is a fine metal mask.

The second mask 30 includes a body 31 and support strips disposed along a periphery of the body 31. A first end of each support strip is connected with the body 31, and the first end of the support strip is a part of the support strip not overlapping with an orthographic projection of the frame 10. A second end disposed opposite to the first end is connected with the frame 10. The body 31 and the support strips are integrally formed.

A plurality of openings 311 for defining a shape of a display region are arranged in an array in the body 31, and a size of the openings 311 is less than a size of the mask strips 21. The support strips include a plurality of first support strips 32 extending along the first direction I and a plurality of second support strips 33 extending along a second direction J perpendicular to the first direction I. The plurality of first support strips 32 are spaced apart along the second direction J, and the plurality of second support strips 33 are spaced apart along the first direction I. That is, the second mask 30 is a full mask sheet. Edges of the body 31 at which the first support strips 32 are disposed are first edges 312 and edges of the body 31 at which the second support strips 33 are disposed are second edges 313.

Widths of the first ends 321 of the outermost first support strips 32 and the first ends 331 of the outermost second support strips 33 gradually increase along a direction from away from the body 31 to close to the body 31, and the first support strips 32 are disposed corresponding to the gaps 22.

Firstly, the outermost first support strips 32 and the outermost second support strips 33 are first support strips 32 and second support strips 33 located at corners of the body 31 of the second mask 30. As mentioned above, it is easy to generate wrinkles at the corners of the body 31 of the second mask 30 during a tensioning process.

The widths of the first ends 321 of the first support strips 32 and the first ends 331 of the second support strips 33 at such positions are disposed as gradually increasing in the direction from away from the body 31 to close to the body 31 (the closer they are to the body 31, the larger the widths of the first support strip 32 and the second support strip 33 are), that is, the widths of the first support strips 32 and the second support strips 33 at the corners of the body 31 of the second mask 30 are gradually widened along the direction from away from the body 31 to close to the body 31, so as to increase the supporting for the body 31. In this way, a pull force for the body 31 during a tensioning process can be better balanced, and a possibility that wrinkles are generated in the first mask 20 can be effectively reduced, thus effectively avoiding edge color mixing.

In this embodiment, portions of two opposed edges of the first ends of the outermost first support strips 32 and the outermost second support strips 33 joining the body 31 are disposed as fillet/rounded corner, such that the widths of the first ends of the outermost first support strips 32 and the outermost second support strips 33 gradually increase along the direction from away from the body 31 to close to the body 31 in a smooth transition manner, thereby facilitating the manufacturing process.

A radius r of an arc forming the rounded corner on the first ends 321 of the outermost first support strips 32 is less than or equal to a distance D from an inner edge of the frame 10 to the first edge 312 of the body 31. That is, the rounded corners located at the first ends 321 of the outermost first support strips 32 are formed only at a position of the outermost first support strips 32 not overlapping with the orthographic projection of the frame 10.

A radius of an arc forming the rounded corner on the first ends 331 of the outermost second support strips 33 is less than or equal to a distance K from the inner edge of the frame 10 to the second edge 313 of the body 31. That is, the rounded corners located at the first ends 331 of the outermost second support strips 33 are formed only at a position of the outermost second support strips 33 not overlapping with the orthographic projection of the frame 10.

The present application is not limited thereto. In another embodiment, the two opposed edges of the first ends 321 of the outermost first support strips 32 and the first ends 331 of the outermost second support strips 33 extend outwardly and obliquely along the direction from away from the body 31 to close to the body 31, such that the widths of the first ends of the outermost first support strips 32 and the outermost second support strips 33 gradually increase along the direction from away from the body 31 to close to the body 31, so as to increase support for the body 31. The two opposed edges of the first ends 321 of the outermost first support strips 32 and the first ends 331 of the outermost second support strips 33 are straight or arched. Alternatively, one of the two opposed edges of the first ends 321 of the first support strips 32 and the first ends 331 of the second support strips 33 is disposed as rounded corner and the other is disposed as extending obliquely, or another combination is used.

In this embodiment, second ends 322 of the first support strips 32 are not overlapped with the mask strips 21. The second ends 322 of the first support strips 32 are parts of the support strips overlapping with the orthographic projection of the frame 10, i.e., ends connected with the frame 10. The second ends 322 of the first support strips 32 are partially fixed to the frame 10 to achieve connection with the frame 10 or wholly fixed to the frame 10 to achieve connection with the frame 10. The second ends 322 of the first support strips 32 are not overlapped with the mask strips 21, which means that the second ends 322 of the first support strips 32 are located between two adjacent mask strips 21, to ensure the mask strips 21 can be kept level when welded to the frame 10.

In an embodiment, a width W of the second end 322 of the first support strip 32 is less than or equal to a width of the gap 22. The second ends 322 of the first support strips 32 are not overlapped with the mask strips 21, that is, the second ends 322 of the first support strips 32 are located between two adjacent mask strips 21 to ensure the mask strips 21 can be kept level when welded to the frame 10.

In this embodiment, a minimum width of the first support strips 32 is equal to the width of the gaps 22, such that the first support strips 32 can provide a supporting force with their maximal width. The width of the second ends 322 of the first support strips 32 is the minimum width of the first support strips 32, which is 1.8 mm to 2.0 mm.

The distance D from the inner edge of the frame 10 to a nearest first edge of the body 31 is greater than 5 mm and less than a size of the opening 311 in the first direction I, and a length of the first support strip 32 is no less than 5 mm longer than the distance D.

The distance K from the inner edge of the frame 10 to a nearest second edge of the body 31 is greater than 5 mm and less than a size of the opening 311 in the second direction J, and a length of the second support strip 33 is no less than 5 mm longer than the distance K.

An interval at which the second support strips 33 are arranged along the first direction I is greater than the size of the openings in the body 31 in the first direction I, so as to avoid influence on the shape of the openings 311. Namely, the spacing between two adjacent second support strips 33 of the second support strips 33 is greater than the size of the openings 311 in the first direction I.

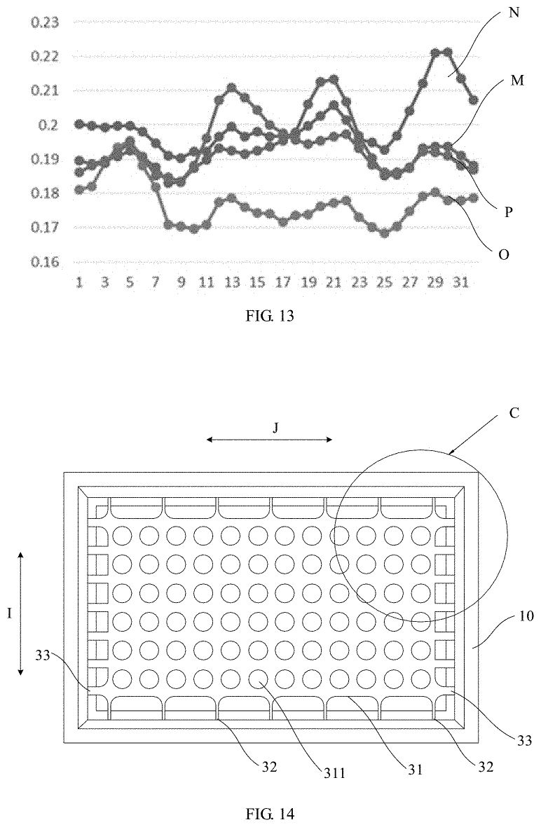

The levelness test results of the openings M, N, O and P of the second mask 30 of the mask assembly 1 in the present embodiment are shown in FIG. 13. It can be seen that an Z value fluctuation of the opening M is 26.85 nm, an Z value fluctuation of the opening N is 30.96 nm, an Z value fluctuation of the opening O is 30.27 nm, and an Z value fluctuation of the opening P is 27.49 nm, all of which are approximate to a wrinkle level of a normal full mask sheet.

The present embodiment further provides an evaporation device, including the above mask assembly 1.

### Embodiment 2

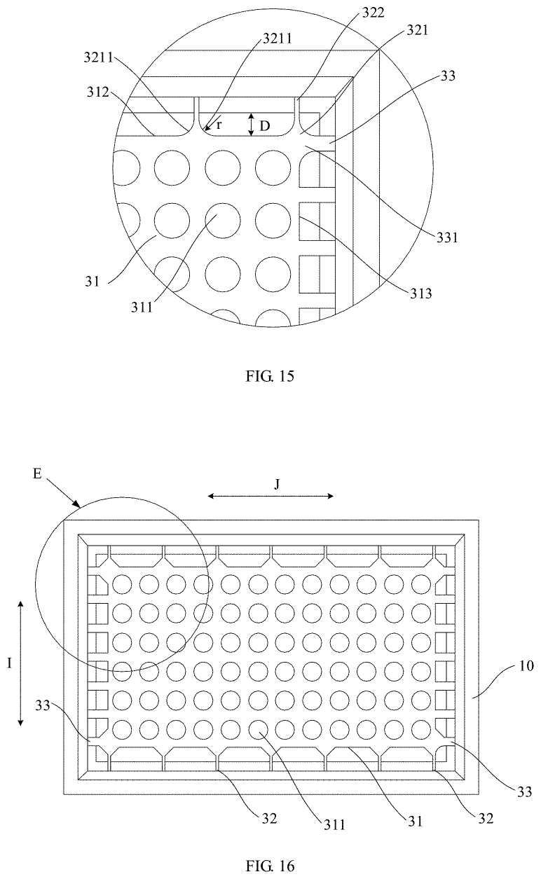

As shown in FIGS. 14 to 19, an overall structure of the mask assembly of the present embodiment is basically same as structure of the embodiment 1. On the basis of the structure of the embodiment 1, in the structure of the mask assembly of the present embodiment, widths of the first ends 321 of other first support strips 32 also gradually increase along the direction from away from the body 31 to close to the body 31. In other words, besides the outermost first support strips 32, the widths of the first ends 321 of the other first support strips 32 also gradually increase along the direction from away from the body 31 to close to the body 31, that is, the widths of the first ends 321 of all the first support strips 32 gradually increase along the direction from away from the body 31 to close to the body 31, so as to further increase support strength of the first support strips 32 for the body 31.

In the present embodiment, the first ends 321 of other first support strips 32 are disposed as rounded corners to enable the widths of the first ends 321 of the other first support strips 32 to gradually increase along the direction from away from the body 31 to close to the body 31 in a smooth transition manner, thus facilitating manufacturing process.

A radius r of an arc forming the rounded corner at the portions of two opposed edges 3211 of the first ends 321 of other first support strips 32 joining the body 31 is less than or equal to the distance D from the inner edge of the frame 10 to the first edge of the body 31. Namely, the rounded corners located at the first ends 321 of the first support strips 32 are formed only at a position of the first support strips 32 not overlapping with the orthographic projection of the frame 10.

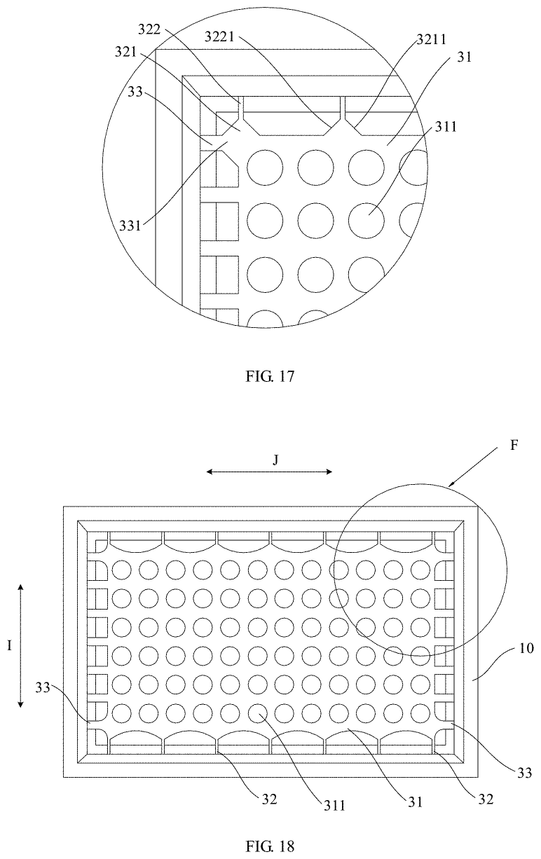

Likewise, same as the embodiment 1, as shown in FIGS. 16 and 17, in another embodiment, the two opposed edges 3211 of the first ends 321 of other first support strips 32 may extend outwardly and obliquely along the direction from away from the body 31 to close to the body 31, such that the widths of the first ends 321 of the other first support strips 32 gradually increase along the direction from away from the body 31 to close to the body 31, so as to increase support for the body 31. The two edges of the first ends 321 of the first support strips 32 may be straight line.

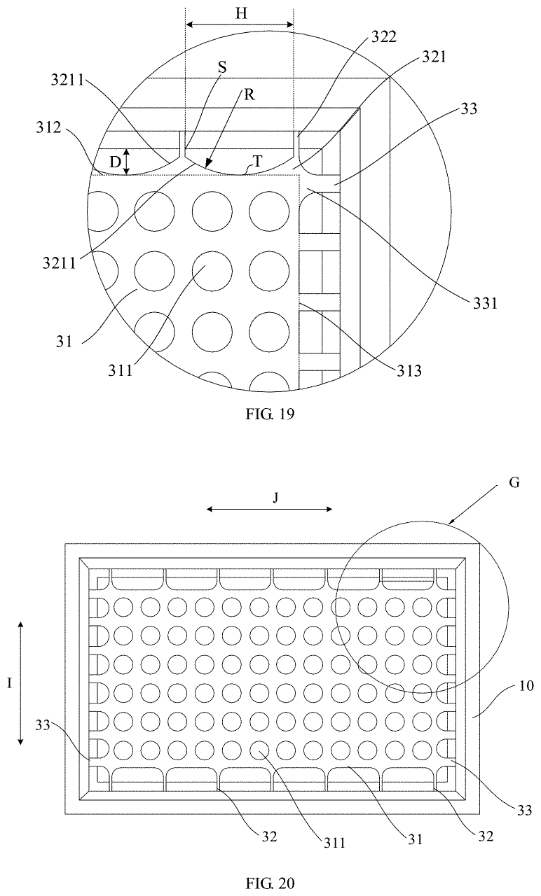

Furthermore, as shown in FIGS. 18 and 19, in another embodiment, the two edges 3211 of the first ends 321 of the first support strips 32 may alternatively be in an arc shape. An end of the arc may be at a position S where the first support strip 32 intersects with the orthographic projection of the frame 10 at the highest level (in FIGS. 18 and 19, the end of the arc is located at a position lower than the highest position S). The other end of the arc is tangent to the first edge 312 of the body 31 with a tangent point at a middle point T of the spacing between two adjacent first support strips 32 at the farthest level (in FIGS. 18 and 19, the other end of the arc is located at the middle point T.).

When one end of the arc is located at the position S where the first support strip 32 intersects with the orthographic projection of the frame 10 and the other end is located at the middle point T of the spacing between two adjacent first support strips 32, the arc is the longest and can be calculated with the following formula:

R=D/2+H²/8D

where R is a radius of the arc, D is a distance between the first edge of the body 31 and the inner edge of the frame 10, and H is a spacing between two adjacent first support strips.

In other embodiments, widths of the first ends 321 of part of other first support strips 32 may gradually increase along the direction from away from the body 31 to close to the body 31. By disposing the first ends 321 of part of other first support strips 32 as rounded corners, their widths can be gradually increased. Alternatively, by disposing the two opposed edges of the first ends 321 of part of other first support strips 32 as extending outwardly and obliquely along the direction from away from the body 31 to close to the body 31, their widths can be gradually increased.

### Embodiment 3

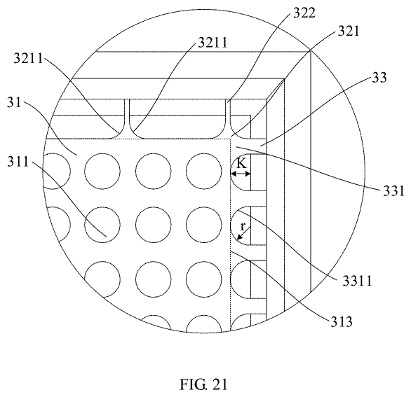

As shown in FIGS. 20 and 21, an overall structure of the mask assembly 1 of the present embodiment is basically same as structure of the embodiment 2, except for the following differences: on the basis of the structure of the embodiment 2, widths of the first ends 331 of other second support strips 33 gradually increase along the direction from away from the body 31 to close to the body 31. Namely, besides the outermost second support strips 33, the widths of the first ends 331 of the other second support strips 33 gradually increase along the direction from away from the body 31 to close to the body 31. That is, the widths of the first ends 331 of all the second support strips 33 gradually increase along the direction from away from the body 31 to close to the body 31, so as to further increase support strength of the second support strips 33 for the body 31.

In the present embodiment, by referring to in FIGS. 21 and 20 again, the first ends 331 of other second support strips 33 are disposed as rounded corner to enable the widths of the first ends 331 of the other second support strips 33 to gradually increase along the direction from away from the body 31 to close to the body 31 in a smooth transition manner, thus facilitating manufacturing process.

A radius r of an arc forming the rounded corners at portions of two opposed edges 3311 of the first ends 331 of other second support strips 33 joining the body 31 is less than or equal to the distance K from the inner edge of the frame 10 to the second edge 313 of the body 31. Namely, the rounded corners located at the first ends 331 of the second support strips 33 are formed only at a position of the second support strips 33 not overlapping with the orthographic projection of the frame 10.

Likewise, same as in the embodiment 1, in another embodiment, two opposed edges of the first ends 331 of other second support strips 33 may extend outwardly and obliquely along the direction from away from the body 31 to close to the body 31, such that the widths of the first ends 331 of the other second support strips 33 can gradually increase along the direction from away from the body 31 to close to the body 31, so as to increase support for the body 31. The two edges of the first ends 331 of the second support strips 33 may be straight line or arc.

In other embodiments, widths of the first ends 331 of part of other second support strips 33 may gradually increase along the direction from away from the body 31 to close to the body 31. By disposing the first ends 331 of part of other second support strips 33 as rounded corner, their widths can be gradually increased. Alternatively, by disposing the two opposed edges of the first ends 331 of part of other second support strips 33 as extending outwardly and obliquely along the direction from away from the body 31 to close to the body 31, their widths can be gradually increased.

The above descriptions are made only to the preferred embodiments of the present application and are not used to limit the present application. Any modifications, equivalent substitutions and improvements made within the spirit and principle of the present application shall all fall within the scope of protection of the present application.

1. A mask assembly, comprising a frame, and a first mask and a second mask stacked on the frame, wherein the first mask is located at a side of the second mask away from the frame;
the first mask comprises a plurality of mask strips disposed along a first direction, a gap is disposed between two adjacent mask strips, and a plurality of pixel openings are arranged in an array in each of the mask strips;
the second mask comprises a body and support strips disposed along a periphery of the body, first ends of the support strips are connected with the body and second ends disposed opposite to the first ends respectively are connected with the frame, a plurality of openings configured to define a shape of a display region are arranged in an array in the body, a size of the openings is less than a size of the mask strips, the support strips comprise a plurality of first support strips extending along the first direction and a plurality of second support strips extending along a second direction perpendicular to the first direction, the plurality of first support strips are spaced apart along the second direction, and the plurality of second support strips are spaced apart along the first direction;
widths of first ends of outermost first support strips and first ends of outermost second support strips gradually increase along a direction from away from the body to close to the body, and the first support strips are disposed corresponding to the gaps.

2. The mask assembly of claim 1, wherein rounded corners are disposed respectively at portions of two opposed edges of the first ends of the outermost first support strips and the first ends of the outermost second support strips joining the body.

3. The mask assembly of claim 1, wherein two opposed edges of the first ends of the outermost first support strips and the first ends of the outermost second support strips extend outwardly and obliquely along the direction from away from the body to close to the body;
the two opposed edges of the first ends of the outermost first support strips and the first ends of the outermost second support strips are straight or arched.

4. The mask assembly of claim 1, wherein,
widths of first ends of at least part of other first support strips gradually increase along the direction from away from the body to close to the body; and/or,
widths of first ends of at least part of other second support strips gradually increase along the direction from away from the body to close to the body.

5. The mask assembly of claim 4, wherein rounded corners are disposed respectively at portions of two opposed edges of the first ends of at least part of the other first support strips joining the body; and/or,
rounded corners are disposed respectively at portions of two opposed edges of the first ends of at least part of the other second support strips joining the body.

6. The mask assembly of claim 1, wherein a width of the second ends of the first support strips is less than or equal to a width of the gaps.

7. The mask assembly of claim 1, wherein a width of the second ends of the first support strips is a minimum width of the first support strips, and the minimum width of the first support strips is 1.8 mm to 2.0 mm.

8. The mask assembly of claim 1, wherein edges of the body at which the first support strips are disposed are first edges and edges of the body at which the second support strips are disposed are second edges;
a distance D from an inner edge of the frame to a nearest first edge of the body is greater than 5 mm and less than a size of the openings in the first direction, and a length of the first support strips is no less than 5 mm longer than the distance D;
a distance K from the inner edge of the frame to a nearest second edge of the body is greater than 5 mm and less than a size of the openings in the second direction, and a length of the second support strips is no less than 5 mm longer than the distance K.

9. The mask assembly of claim 1, wherein a distance between two adjacent second support strips is greater than the size of the openings in the first direction.

10. An evaporation device, comprising a mask assembly including a frame, and a first mask and a second mask stacked on the frame, wherein the first mask is located at a side of the second mask away from the frame;
the first mask comprises a plurality of mask strips disposed along a first direction, a gap is disposed between two adjacent mask strips, and a plurality of pixel openings are arranged in an array in each of the mask strips;
the second mask comprises a body and support strips disposed along a periphery of the body, first ends of the support strips are connected with the body and second ends disposed opposite to the first ends respectively are connected with the frame, a plurality of openings configured to define a shape of a display region are arranged in an array in the body, a size of the openings is less than a size of the mask strips, the support strips comprise a plurality of first support strips extending along the first direction and a plurality of second support strips extending along a second direction perpendicular to the first direction, the plurality of first support strips are spaced apart along the second direction, and the plurality of second support strips are spaced apart along the first direction;
widths of first ends of outermost first support strips and first ends of outermost second support strips gradually increase along a direction from away from the body to close to the body, and the first support strips are disposed corresponding to the gaps.

11. The evaporation device of claim 10, wherein rounded corners are disposed respectively at portions of two opposed edges of the first ends of the outermost first support strips and the first ends of the outermost second support strips joining the body.

12. The evaporation device of claim 10, wherein two opposed edges of the first ends of the outermost first support strips and the first ends of the outermost second support strips extend outwardly and obliquely along the direction from away from the body to close to the body;
the two opposed edges of the first ends of the outermost first support strips and the first ends of the outermost second support strips are straight or arched.

13. The evaporation device of claim 10, wherein,
widths of first ends of at least part of other first support strips gradually increase along the direction from away from the body to close to the body; and/or,
widths of first ends of at least part of other second support strips gradually increase along the direction from away from the body to close to the body.

14. The evaporation device of claim 13, wherein rounded corners are disposed respectively at portions of two opposed edges of the first ends of at least part of the other first support strips joining the body; and/or,
rounded corners are disposed respectively at portions of two opposed edges of the first ends of at least part of the other second support strips joining the body.

15. The evaporation device of claim 10, wherein a width of the second ends of the first support strips is less than or equal to a width of the gaps.

16. The evaporation device of claim 10, wherein a width of the second ends of the first support strips is a minimum width of the first support strips, and the minimum width of the first support strips is 1.8 mm to 2.0 mm.

17. The evaporation device of claim 10, wherein edges of the body at which the first support strips are disposed are first edges and edges of the body at which the second support strips are disposed are second edges;
a distance D from an inner edge of the frame to a nearest first edge of the body is greater than 5 mm and less than a size of the openings in the first direction, and a length of the first support strips is no less than 5 mm longer than the distance D;
a distance K from the inner edge of the frame to a nearest second edge of the body is greater than 5 mm and less than a size of the openings in the second direction, and a length of the second support strips is no less than 5 mm longer than the distance K.

18. The evaporation device of claim 10, wherein a distance between two adjacent second support strips is greater than the size of the openings in the first direction.
